(19) United States
(12) Patent Application Publication
(10) Pub. No.: US 2009/0051031 A1
(43) Pub. Date: Feb. 26, 2009

(54) Package structure and manufacturing method thereof

(75) Inventors: Yi-Shao Lai, Yonghe City (TW); Tsung-Yueh Tsai, Kaohsiung (TW)

Correspondence Address: BACON & THOMAS, PLLC, 625 SLATERS LANE, FOURTH FLOOR, ALEXANDRIA, VA, 22314-1176, US

(73) Assignee: Advanced Semiconductor Engineering, Inc., Kaohsiung (TW)

(21) Appl. No.: 12/219,955

(22) Filed: Jul. 31, 2008

(30) Foreign Application Priority Data
Aug. 21, 2007 (TW) 96130961

(51) Int. Cl. H01L 23/488; H01L 21/56

(52) U.S. Cl. 257/738; 438/118; 257/E23.023; 257/E21.502

(57) ABSTRACT

A package structure and a manufacturing method thereof are provided. The package structure comprises a carrier, a chip, at least one wire, a molding compound, at least one first solder ball and at least one second solder ball. The carrier has a chip chamber passing through the first surface and the second surface. The chip is disposed in the chip chamber, and an active surface of the chip is coplanar with the first surface. During packaging, the first surface and the active surface are both tightly pasted on a carrier tape to facilitate the subsequent wire bonding and sealing process. Afterwards, the carrier tape is removed for exposing the active surface and the first surface, and the active surface of the chip is coplanar with the first surface of the carrier, hence simplifying the packaging process and reducing the thickness of the package structure.

This application claims the benefit of Taiwan application Serial No. 96130961, filed Aug. 21, 2007, the subject matter of which is incorporated herein by reference.

### BACKGROUND OF THE INVENTION

1. Field of the Invention

The invention relates in general to a package structure and a manufacturing method thereof, and more particularly to a package structure having a carrier with a chip chamber passing through a first surface and a second surface of the carrier such that an active surface of the chip faces downward and is coplanar with the first surface of the carrier and a manufacturing method thereof.

2. Description of the Related Art

As electronic products are directed towards multifunction, high quality, miniaturization and lightweight, numerous methods, such as wire bonding, flip-chip packaging and chip size packaging, are provided for packaging the package structure of an electronic product.

To shorten the transmission distance of electronic signals between the chip and the carrier of a package structure and to reduce the size of a packaged chip package, the chip can be bound on the carrier by way of flip-chip bonding, as indicated in FIG. 1, a cross-sectional view of a conventional package structure is illustrated. The conventional package structure 100 includes a carrier 110, a chip 120, numerous bumps 130 and a molding compound 140. The carrier 110 has a first surface 111 and a second surface 112 opposite to the first surface 111, and these solder pads 113 are formed on the first surface 111. The chip 120 has an active surface 121 and a rear surface 122 opposite to the active surface 121, and these solder pads 123 are formed on the active surface 121. The bumps 130 are used for electrically connecting the connecting pads 113 of the carrier 110 with the solder pads 123 of the chip 120. The molding compound 140 is formed between the carrier 110 and the chip 120 for protecting the bumps 130. The package structure 100 further includes numerous solder balls 150 formed on the second surface 112 of the carrier 110 for electrically connecting with a printed circuit board (not illustrated).

Prior to the filling of the molding compound 140 into the conventional package structure 100, the bumps 130 must be formed between the chip 120 and the carrier 110 before the bumps 130 are reflown subsequently. After filling the molding compound 140, numerous solder balls 150 are formed on the second surface 112 of the carrier 110. Then, these solder balls 150 are reflown. Therefore, the manufacturing process of the conventional package structure 100 is very complicated. In addition to that, the chip 120 of the conventional package structure 100 is stacked on the carrier 110 and is coupled to the carrier 110 via these bumps 130 disposed therebetween. As a result, the conventional package structure 100 becomes thicker and occupies a larger space in an electronic product.

U.S. Pat. Nos. 6,906,414, 5,541,450 and 5,717,252 respectively disclose a package structure, in which a chip is disposed on a substrate by way of an enhancement substrate or a support substrate. Despite the package structures is a little lower than the conventional package structure in FIG. 1, the package structure is still complicated, and the package size is still incomformable to the develop trend of electronic products nowadays. Therefore, further improvement is essential.

To resolve the above shortcomings of the prior art, a low profile package structure with a rear surface of the chip facing downward and being exposed is disclosed in U.S. Pat. No. 5,696,666. However, a downward rear surface does not meet current needs of the package structure, and the packaging method of such package structure is not disclosed in its disclosure. Thus, it is still insufficient for wide application.

### SUMMARY OF THE INVENTION

The invention is directed to a package structure and a manufacturing method thereof for simplifying the manufacturing process and reducing the thickness of the package structure.

According to a first aspect of the present invention, a package structure including a carrier, a chip, at least one wire, a molding compound, at least one first solder ball and at least one second solder ball is provided. The carrier includes a chip chamber, a first surface and a second surface opposite to the first surface. The chip chamber passes through the first surface and the second surface. The first surface has at least one first connecting pad. The second surface has at least one second connecting pad. The chip is disposed in the chip chamber of the carrier. The chip has an active surface and a rear surface opposite to the active surface. The active surface is coplanar with the first surface of the carrier. The active surface has at least one first solder pad, and the rear surface has at least one second solder pad. The wire is disposed between the chip and the carrier for electrically connecting the second solder pad of the chip and the second connecting pad of the carrier. The molding compound is disposed on the second surface of the carrier for filling up the chip chamber. The molding compound covers part of the chip, the second solder pad of the chip, the wire, the second surface of the carrier and the second connecting pad of the carrier, and exposes the active surface of the chip, the first surface of the carrier, the first solder pad of the chip and the first connecting pad of the carrier. The first solder ball is disposed on the first solder pad on the active surface of the chip. The second solder ball is disposed on the first connecting pad on the first surface of the carrier.

According to a second aspect of the present invention, a manufacturing method of package structure is provided. The method includes the following steps:

providing a carrier including a chip chamber, a first surface and a second surface opposite to the first surface, the chip chamber passing through the first surface and the second surface, the first surface having at least one first connecting pad, and the second surface having at least one second connecting pad;

providing a carrier tape disposed on the first surface of the carrier for sealing the opening at one end of the chip chamber;

disposing a chip in the chip chamber of the carrier, the chip having an active surface and a rear surface opposite to the active surface, the active surface being tightly pasted on the carrier tape, the active surface having at least one first solder pad, and the rear surface having at least one second solder pad;

forming at least one wire between the chip and the carrier for electrically connecting the second solder pad of the chip with the second connecting pad of the carrier;

forming a molding compound on the second surface of the carrier for filling up the chip chamber, the molding compound covering part of the chip, the second solder pad of the chip, the wire, the second surface of the carrier, and the second connecting pad of the carrier;

removing the carrier tape for exposing the active surface of the chip, the first surface of the carrier, the first solder pad of the chip, and the first connecting pad of the carrier;

forming at least one first solder ball on the first solder pad of the active surface of the chip; and

forming at least one second solder ball on the first connecting pad of the first surface of the carrier.

Compared with the prior art, the package structure of the invention forms a chip chamber passing through the first surface and the second surface of the carrier. The chip is disposed with its active surface facing downward, and is coplanar with the first surface of the carrier, hence reducing the thickness of the package structure, shortening the path for electrical transmission, and improving heat dissipation. During manufacturing process, as the first surface of the carrier and the active surface of the chip are tightly pasted on the carrier tape, the manufacturing process of the package structure is thus simplified.

The invention will become apparent from the following detailed description of the preferred but non-limiting embodiment. The following description is made with reference to the accompanying drawings.

### BRIEF DESCRIPTION OF THE DRAWINGS

FIG. 1 shows a conventional package structure.

FIG. 2A shows a carrier of the invention.

FIG. 2B shows the carrier of the invention disposed on a carrier tape.

FIG. 2C shows a chip of the invention disposed on the carrier and the carrier tape.

FIG. 2D shows a plurality of wires of the invention.

FIG. 2E shows an underfill of the invention formed on the second surface of the carrier.

FIG. 2F shows a perspective after the carrier tape of the invention is removed.

FIG. 2G shows a package structure of the invention.

FIG. 3 is a flowchart diagram of a method for packaging a package structure of the invention.

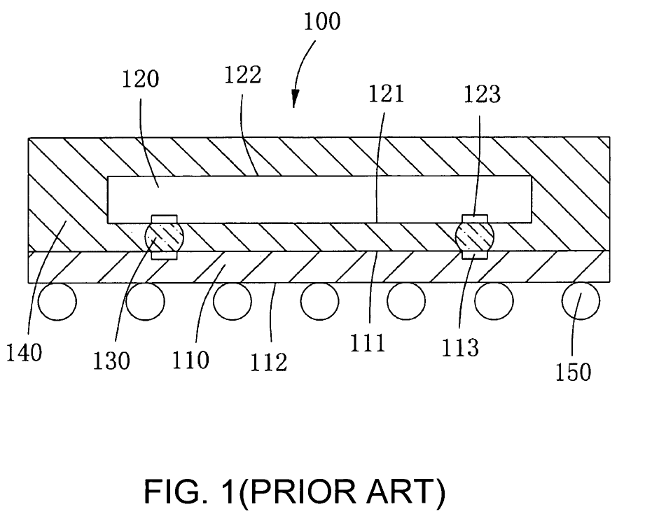

### DETAILED DESCRIPTION OF THE INVENTION

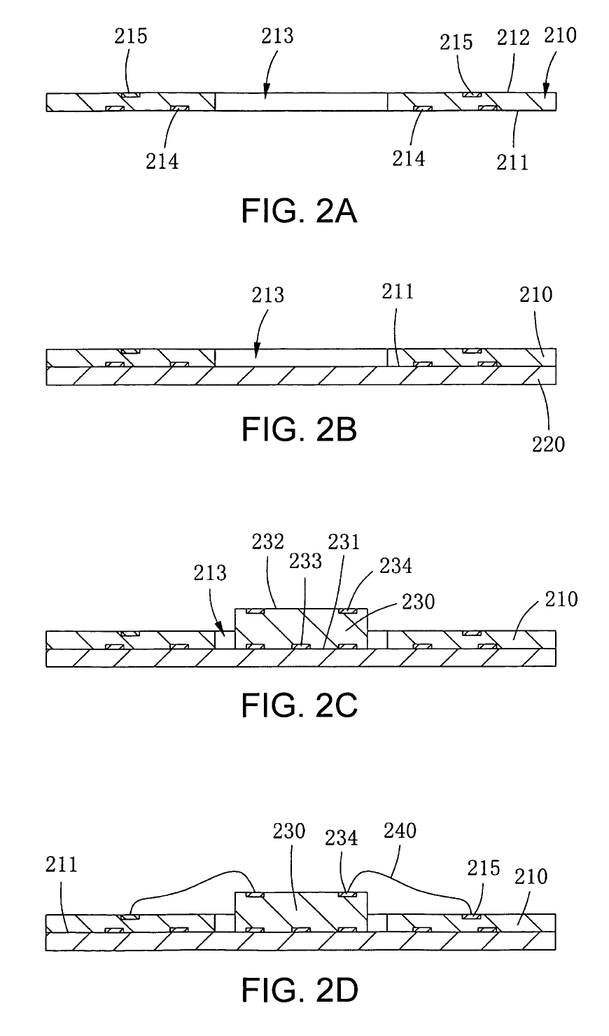

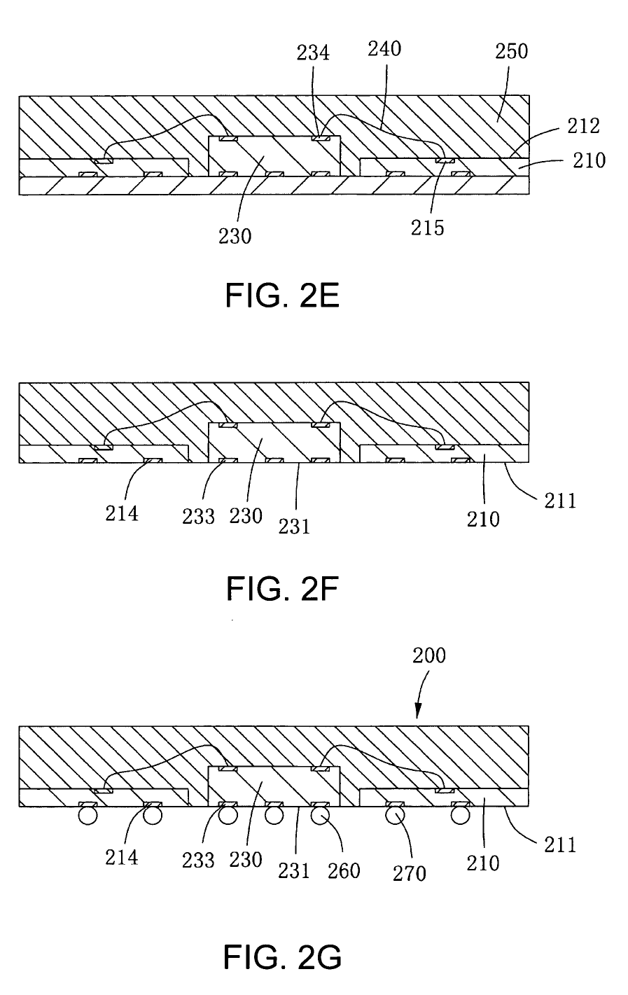

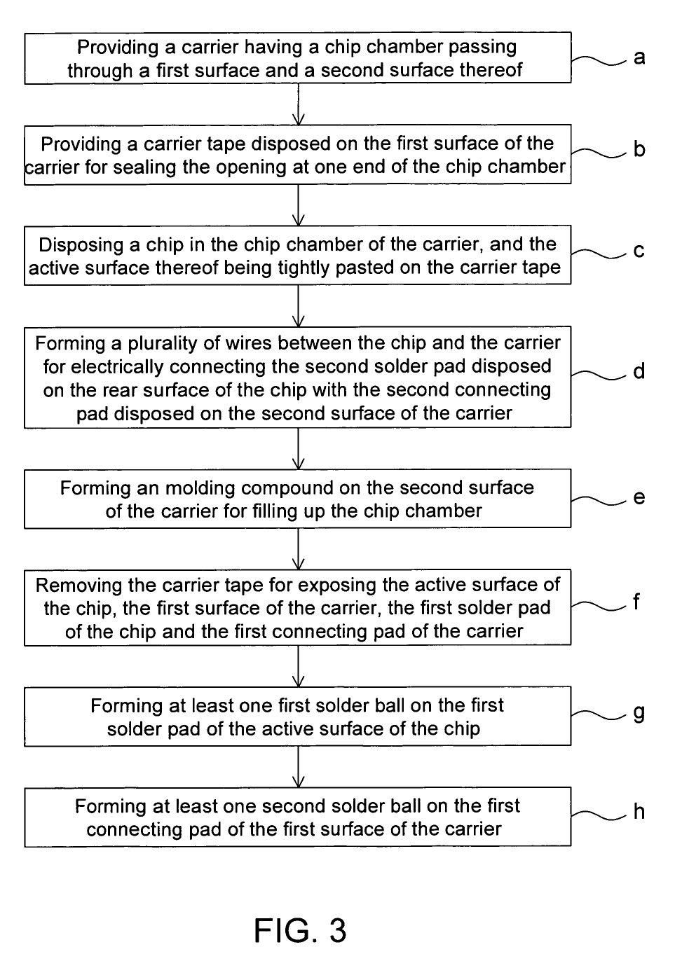

The details of the method of manufacturing package structure are disclosed in the present embodiment of the invention with the structural diagrams illustrated in FIGS. 2A-2G and the flowchart shown in FIG. 3.

Referring to FIG. 2A and step a in FIG. 3, firstly, a carrier 210 having a first surface 211, a second surface 212 and a chip chamber 213 is provided. The first surface 211 is opposite to the second surface 212, and the chip chamber 213 passes through the first surface 211 and the second surface 212 for receiving the chip (as indicated in FIG. 2C). The first surface 211 of the carrier 210 has numerous first connecting pads 214, and the second surface 212 has numerous second connecting pads 215. The first connecting pads 214 and the second connecting pads 215 are made from metal, such as copper, nickel, tin, gold or combination thereof. In the present embodiment of the invention, the carrier 210 comprises at least one conductive through hole (not illustrated) passing through the first surface 211 and the second surface 212 for electrically connecting one of the first connecting pads 214 with one of the second connecting pads 215.

Referring to FIG. 2B and step b in FIG. 3, a carrier tape 220 is provided. The carrier 210 is disposed on the carrier tape 220, and the first surface 211 of the carrier 210 contacts with the carrier tape 220. One end of the opening of the chip chamber 213 at the first surface 211 is sealed by the carrier tape 220. In the present embodiment of the invention, the carrier tape 220 is an adhesive tape for example, and the carrier 210 is adhered onto the adhesive tape via the first surface 211. The carrier tape 220 is not limited to an adhesive tape. An engaging mechanism (not illustrated) can be disposed on the carrier tape 220 for fixing the carrier 210 on the carrier tape 220.

Referring to FIG. 2C and step c in FIG. 3, a chip 230 is disposed in the chip chamber 213 of the carrier 210. The chip 230 has an active surface 231 and a rear surface 232 opposite to the active surface 231. The active surface 231, having numerous first solder pads 233 thereon, faces downward and is tightly pasted on the carrier tape 220. The rear surface 232 of the chip 230 has numerous second solder pads 234. In the present embodiment of the invention, the first solder pads 233 and the second solder pads 234 individually have at least one Input/Output solder pad (not illustrated). In other words, the active surface 231 and the rear surface 232 of the chip 230 individually have at least one Input/Output solder pad. The chip 230 further has at least one conductive through hole (not illustrated) passing through the active surface 231 and the rear surface 232 for electrically connecting one of the first solder pads 233 with one of the second solder pads 234.

Referring to FIG. 2D and step d in FIG. 3, a wire bonding process is performed, so as to form numerous wires 240 between the chip 230 and the carrier 210. The wire bonding process is for connecting the signals in the chip 230 to the carrier 210. The carrier 210 has an interior route, and the signals of the chip 230 are connected to the solder balls (the second solder balls 270 in FIG. 2G) disposed on the bottom surface (the first surface 211) of the carrier 210 via the first connecting pads 214 and the second connecting pads 215. The wires 240 are normally made from gold or aluminum for electrically connecting the second solder pads 234 disposed on the chip 230 with the second connecting pads 215 that are disposed on the carrier 210 and corresponding to the second solder pads 234.

Referring to FIG. 2E and step e in FIG. 3, a molding compound 250 is formed on the second surface 212 of the carrier 210 for filling up the chip chamber 213. The molding compound 250 covers part of the chip 230 (such as the rear surface 232 and two lateral sides of the chip 230), the second solder pads 234 of the chip 230, the wires 240, the second surface 212 of the carrier 210 and the second connecting pads 215 of the carrier 210 for protecting these structures.

Referring to FIG. 2F and step f in FIG. 3, the carrier tape 220 is removed for exposing the active surface 231 of the chip 230, the first surface 211 of the carrier 210, the first solder pads 233 of the chip 230 and the first connecting pads 214 of the carrier 210. After the carrier tape 220 is removed, the active surface 231 of the chip 230 faces downward. The active surface 231 is exposed and is coplanar with the first surface 211 of the carrier 210, not only reducing the overall height of the package structure, but also increasing heat dissipation effect and electrical transmission effect as well.

Referring to FIG. 2G and steps g and h in FIG. 3, numerous first solder balls 260 are disposed on the first solder pads 233 of the active surface 231 of the chip 230, and numerous second solder balls 270 are disposed on the first connecting pads 214 of the first surface 211 of the carrier 210 to form a package structure 200.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A package structure, comprising:
a carrier comprising a chip chamber, a first surface and a second surface, the first surface being opposite to the second surface, the chip chamber passing through the first surface and the second surface, wherein the first surface has at least one first connecting pad, and the second surface has at least one second connecting pad;
a chip disposed in the chip chamber of the carrier, the chip having an active surface and a rear surface opposite to the active surface, the active surface being coplanar with the first surface of the carrier, wherein the active surface has at least one first solder pad, and the rear surface has at least one second solder pad;
at least one wire disposed between the chip and the carrier for electrically connecting the second solder pad of the chip with the second connecting pad of the carrier;
a molding compound disposed on the second surface of the carrier for filling up the chip chamber, wherein the molding compound covers part of the chip, the second solder pad of the chip, the wire, the second surface of the carrier and the second connecting pad of the carrier and exposes the active surface of the chip, the first surface of the carrier, the first solder pad of the chip and the first connecting pad of the carrier;
at least one first solder ball disposed on the first solder pad of the active surface of the chip; and
at least one second solder ball disposed on the first connecting pad of the first surface of the carrier.

2. The package structure according to claim 1, wherein the chip comprises at least one conductive through hole passing through the active surface and the rear surface for electrically connecting the first solder pad and the second solder pad.

3. The package structure according to claim 1, wherein the active surface and the rear surface of the chip individually have an Input/Output solder pad.

4. The package structure according to claim 3, wherein the carrier comprises at least one conductive through hole passing through the first surface and the second surface for electrically connecting the first connecting pad and the second connecting pad.

5. A manufacturing method of package structure, comprising:
providing a carrier comprising a chip chamber, a first surface and a second surface, the first surface being opposite to the second surface, the chip chamber passing through the first surface and the second surface, wherein the first surface has at least one first connecting pad, and the second surface has at least one second connecting pad;
providing a carrier tape disposed on the first surface of the carrier for sealing the opening at one end of the chip chamber;
disposing a chip in the chip chamber of the carrier, the chip having an active surface and a rear surface opposite to the active surface, the active surface being tightly pasted on the carrier tape, wherein the active surface has at least one first solder pad, and the rear surface has at least one second solder pad;
forming at least one wire between the chip and the carrier for electrically connecting the second solder pad of the chip with the second connecting pad of the carrier;
forming a molding compound on the second surface of the carrier for filling up the chip chamber, wherein the molding compound covers part of the chip, the second solder pad of the chip, the wire, the second surface of the carrier and the second connecting pad of the carrier;
removing the carrier tape for exposing the active surface of the chip, the first surface of the carrier, the first solder pad of the chip and the first connecting pad of the carrier;
forming at least one first solder ball on the first solder pad on the active surface of the chip; and
forming at least one second solder ball on the first connecting pad on the first surface of the carrier.

6. The manufacturing method of package structure according to claim 5, wherein the carrier tape has an engaging mechanism via which the carrier is fixed on the carrier tape.

7. The manufacturing method of package structure according to claim 5, wherein the carrier tape is a tape onto which the carrier is adhered.

8. The manufacturing method of package structure according to claim 5, wherein the carrier comprises at least one conductive through hole passing through the first surface and the second surface for electrically connecting the first connecting pad with the second connecting pad.

9. The manufacturing method of package structure according to claim 5, wherein the chip has at least one conductive through hole passing through the active surface and the rear surface for electrically connecting the first solder pad with the second solder pad.

10. The manufacturing method of package structure according to claim 5, wherein the active surface and the rear surface of the chip individually have an Input/Output solder pad.
